(19) United States
(12) Patent Application Publication
(10) Pub. No.: US 2026/0367191 A1
(43) Pub. Date: Nov. 19, 2026

(54) MAGNETIC FIELD SENSOR

(71) Applicant: Allegro MicroSystems, LLC, Manchester, NH (US)

(72) Inventor: Hernán D. Romero, Buenos Aires (AR)

(73) Assignee: Allegro MicroSystems, LLC, Manchester, NH (US)

(21) Appl. No.: 19/207,786

(22) Filed: May 14, 2025

(51) Int. Cl. G01R 33/00; G01R 33/09

(52) U.S. Cl. CPC G01R 33/0029; G01R 33/09

(57) ABSTRACT

A sensor comprising: a sensing bridge including a plurality of primary MR elements; an offset trimming circuit that includes one or more secondary MR elements, and a current source, wherein the current source is configured to generate an offset compensation signal based on a reference signal that is produced at least in part by the one or more secondary MR elements, and inject the offset compensation signal in the sensing bridge.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with proximity, or motion of a target object, or the flow of electric current through a conductor. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a sensor is provided comprising: a sensing bridge including a first primary magnetoresistance (MR) element, a second primary MR element, a third primary MR element, and a fourth primary MR element, the first primary MR element being coupled in series with the second primary MR element to form a first leg of the sensing bridge, the third primary MR element being coupled in series with the fourth primary MR element to form a second leg of the sensing bridge, the first leg being coupled in parallel with the second leg, the first primary MR element including a first network of MR structures, the second primary MR element including a second network of MR structures, the third primary MR element including a third network of MR structures, and the fourth primary MR element including a fourth network of MR structures; an offset trimming circuit that includes one or more secondary MR elements and a first current source, wherein the first current source and the one or more secondary MR elements are configured to generate an offset compensation signal and inject the offset compensation signal in one of the first network or the third network; and a sensitivity mismatch trimming circuit that includes a non-magnetic resistor and a second current source, wherein the second current source and the non-magnetic resistor are configured to generate a sensitivity compensation signal and inject the sensitivity compensation signal in at least one of the second network and/or the fourth network.

According to aspects of the disclosure, a sensor is provided comprising: a sensing bridge including a plurality of primary MR elements; an offset trimming circuit that includes one or more secondary MR elements, and a current source, wherein the current source is configured to generate an offset compensation signal based on a reference signal that is produced at least in part by the one or more secondary MR elements, and inject the offset compensation signal in the sensing bridge.

According to aspects of the disclosure, a sensor is provided comprising: a sensing bridge including a plurality of primary MR elements; a sensitivity trimming circuit that includes a non-magnetic resistor, and a current source, wherein the current source is configured to generate a sensitivity compensation signal based on a reference signal that is produced at least in part by the non-magnetic resistor, and inject the sensitivity compensation signal in the sensing bridge.

### BRIEF DESCRIPTION OF THE DRAWINGS

The foregoing features may be more fully understood from the following description of the drawings in which:

FIG. 1 is a diagram of an example of a sensing element, according to aspects of the disclosure;

FIG. 2 is a diagram of an example of a sensing bridge, according to aspects of the disclosure;

FIG. 3 is a diagram of an example of a sensor according to aspects of the disclosure;

FIG. 4 is a diagram of an example of an offset trimming circuit according to aspects of the disclosure;

FIG. 5 is a diagram of an example of a sensitivity trimming circuit, according to aspects of the disclosure;

FIG. 6 is a diagram of an example of a sensor, according to aspects of the disclosure;

FIG. 7 is a diagram of an example a resistor, according to aspects of the disclosure; and

FIG. 8 is a diagram of an example of a sensing element.

### DETAILED DESCRIPTION

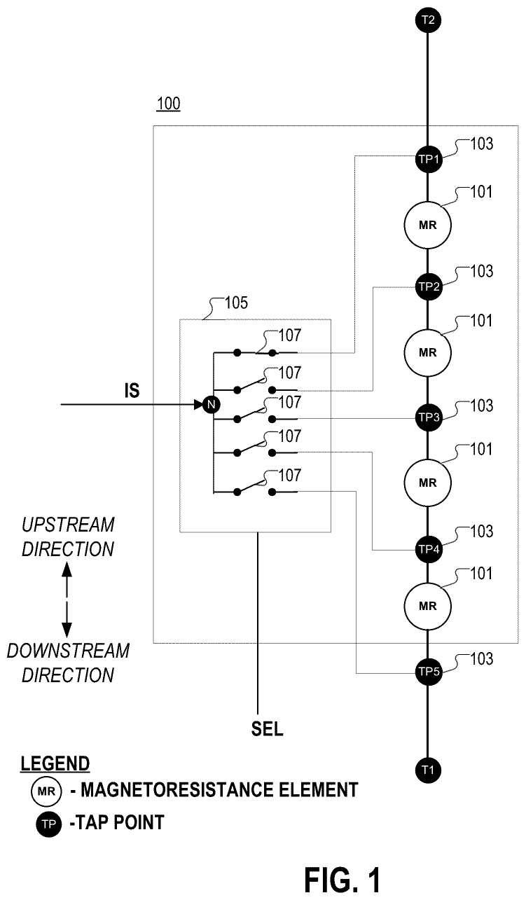

FIG. 1 illustrates a diagram of an example of a magnetoresistance (MR) element 100, in accordance with certain aspects of the disclosure. As shown, MR element 100 comprises a series of magnetoresistance (MR) pillars 101 that connect between terminals T1 and T2 of the MR element. For simplicity only pillars in series are shown, however, in some implementations, at least some of the pillars may be arranged in parallel. Tap points 103 are located at various positions within the circuit linking the MR pillars 101. A switching circuit 105 is integrated into MR element 100 and is designed to direct an injected signal (IS) to one of the tap points 103. The switching circuit 105 receives the signal IS at node N. The switching circuit 105 may contain several switches 107, each connected between node N and a different tap point 103. The operation of switches 107 is determined by a control signal (SEL). This control signal SEL is a multi-bit signal where each bit corresponds to a specific switch. For example, if a bit is set to ‘0,’ the switch remains open, while a ‘1’ setting closes the switch.

In the context of this disclosure, the signal IS is referred to as the “injection signal” of MR element 100. Similarly, the signal SEL is termed the “selection signal” of MR element 100. The injection signal IS is considered to be injected into the network of MR pillars that form MR element 100 when it is routed to any of the tap points (TP1, TP2, TP3, TP4, and TP5). Notably, injecting signal IS into either tap points TP1 or TP5 is equivalent to injecting it into an output line of a sensing bridge, of which the MR element 100 is a component or between the MR element 100 and another MR element that is part of the sensing bridge. The injected signal IS can be either the signal IOFF or ISMM, which are discussed in greater detail below.

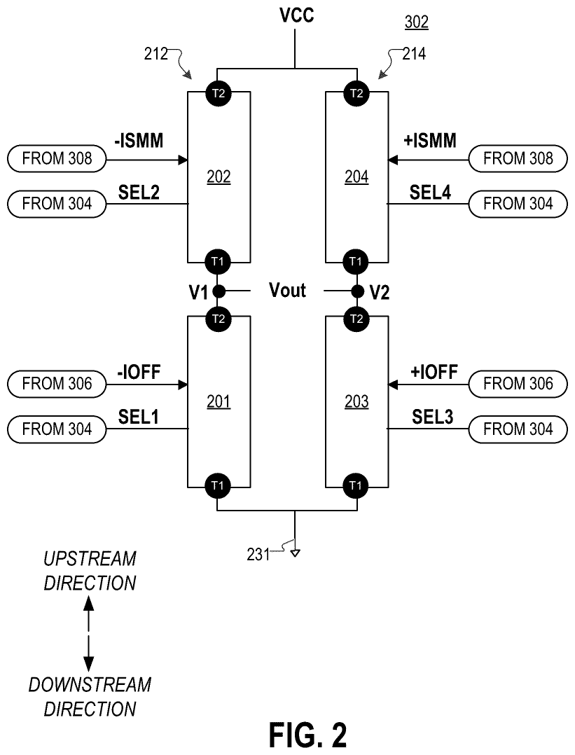

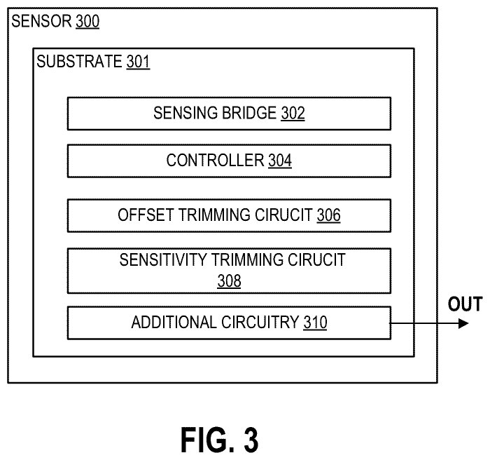

FIG. 2 shows a diagram of an example of a sensing bridge 302, according to various aspects of the disclosure. The sensing bridge 302 may include legs 212 and 214 that are connected in parallel between a voltage source (Vcc) (or a current source) and a reference potential 231 (such as ground). Leg 212 includes MR elements 201 and 202, which are connected in series, while leg 214 includes of MR elements 203 and 204, also connected in series. In the example of FIG. 2, each of these MR elements (201, 202, 203, and 204) is identical to MR element 100. The injection signal for MR element 201 is designated as IOFF, and its selection signal is labeled SEL1. For MR element 202, the injection signal is ISMM, with the selection signal marked as SEL2. MR element 203 has the injection signal IOFF and selection signal SEL3, while MR element 204 has the injection signal ISMM and selection signal SEL4. The output signal (Vout) from sensing bridge 302 is provided at nodes V1 and V2, as illustrated. In this example, terminal T1 of MR elements 201 and 203 is connected to the reference potential 231, while terminal T2 of MR elements 202 and 204 is connected to the voltage source Vcc. Terminal T1 of MR element 202 is coupled to terminal T2 of MR element 201, and terminal T1 of MR element 204 is connected to terminal T2 of MR element 203. The selection signals (SEL1, SEL2, SEL3, and SEL4) are generated by the controller of a magnetic field sensor that includes sensing bridge 302 (for example, controller 304, as shown in FIG. 3). The IOFF signal is produced by the offset trimming circuit of the sensor (e.g., circuit 306, as described in FIG. 3), and the ISMM signal is generated by a sensitivity trimming circuit that is part of the sensor (e.g., circuit 308, also illustrated in FIG. 3). In the present example, both of signals IOFF and ISMM are current signals.

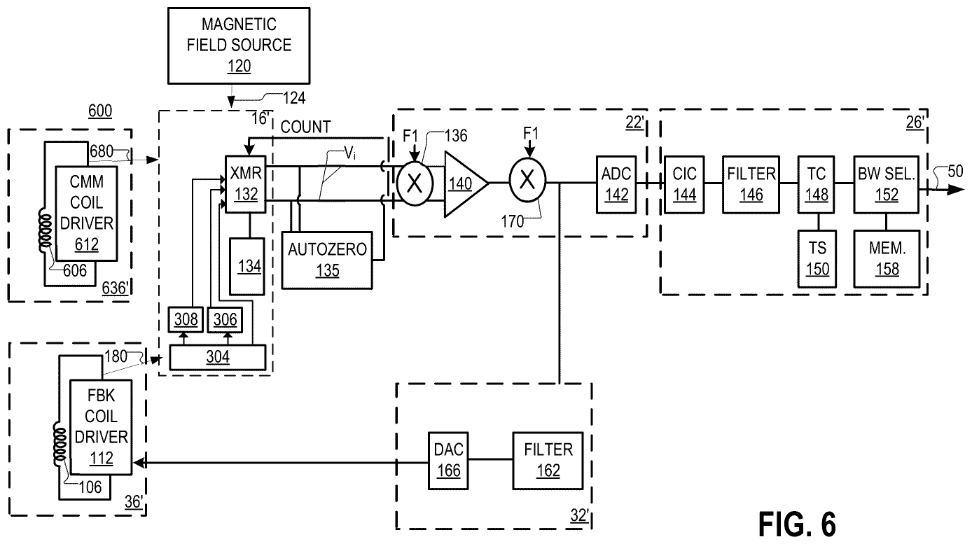

FIG. 3 illustrates an example of a sensor 300, according to aspects of the disclosure. Sensor 300 can be any suitable type of magnetic field sensor, such as a current sensor, position sensor, or angle sensor. As shown, sensor 300 may include a substrate 301, a sensing bridge 302, a controller 304, an offset trimming circuit 306, a sensitivity mismatch trimming circuit 308, and additional circuitry 310. The sensitivity mismatch trimming circuit may be configured to trim the difference between the sensitivities of the MR elements in sensing bridge 302. Trimming the difference between the sensitivities of the MR elements in sensing bridge 302 should be distinguished from trimming the absolute sensitivity value of sensing bridge 302. The substrate 301 may include a silicon substrate or any other suitable type of substrate. The sensing bridge 302, controller 304, offset trimming circuit 306, sensitivity mismatch trimming circuit 308, and additional circuitry 310 may all be formed on substrate 301. The controller 304 can include one or more of digital logic, a general-purpose processor, a special-purpose processor, or any other suitable type of analog or digital processing circuitry. The offset trimming circuit 306 is configured to generate a signal IOFF that is injected into specific tapping points in one of the MR elements within the sensing bridge 302 in order to cancel an offset that is imparted on the output Vout of sensing bridge 302 due to electrical imbalances in sensing bridge 302. The sensitivity mismatch trimming circuit 308 is configured to generate a signal ISMM that is injected into specific tapping points in one of the MR elements within the sensing bridge 302 in order to correct for a sensitivity mismatch between any of the MR elements in sensing bridge 302. The additional circuitry 310 may encompass any processing circuitry typically found in magnetic field sensors, which can include amplifiers, analog-to-digital converters (ADCs), digital-to-analog converters (DACs), and filters (either digital or analog). For example, and without limitation, in sensor 600, which is shown in FIG. 6, the additional circuitry 310 may include all other circuitry that is shown in FIG. 6 other than the controller 304, the sensing bridge, and the circuits 306 and 308. In the example of FIG. 3, the additional circuitry 310 is configured to receive the output (Vout) from the sensing bridge 302 and generate an output signal (OUT) in response. The output signal OUT can then be provided to external circuitry connected to the sensor 300. Additionally or alternatively, in some implementations, the additional circuitry 310 may include one or more calibration coils and a driver for driving the calibration coils. In the example of FIG. 6, a secondary coil circuitry 636′ is shown that includes a common mode coil 606 and a common mode coil driver 612.

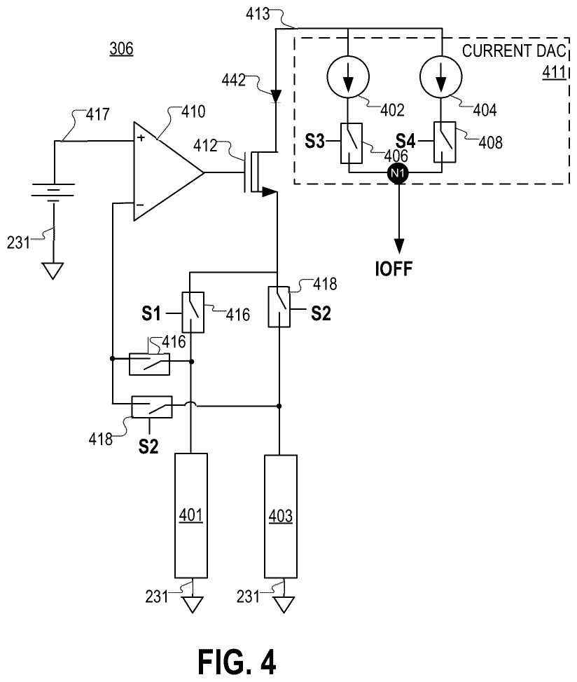

FIG. 4 is a diagram of an example of an offset trimming circuit 306, according to aspects of the disclosure. As illustrated, circuit 306 may include an amplifier 410, a transistor 412, magnetoresistance (MR) elements 401 and 403, switches 416 and 418, and a current digital-to-analog converter (DAC) 411.

Transistor 412, according to the present example, is a Metal Oxide Field Effect transistor (MOSFET). However, the present disclosure is not limited to using any specific type of transistor; for example, transistor 412 may be a bipolar junction transistor (BJT), and/or any other suitable type of transistor.

MR elements 401 and 403 are configured to respond to external fields in the same way as MR elements 201 and 203. The external fields may include one or more of stray fields, differential fields, and/or other suitable type of magnetic field. These MR elements can be tunnel magnetoresistance (TMR) elements or any other appropriate type of magnetoresistive element, such as a giant magnetoresistance (GMR) element. In some implementations, MR element 401 may be co-located with MR element 201, while MR element 403 may be co-located with MR element 203. Additionally, MR elements 401 and 201 may be formed in a first region of substrate 301, and MR elements 403 and 203 may be formed in a second region of substrate 301. Moreover, the distance between MR elements 401 and 201 may be shorter than the distance between MR element 401 and any of the other MR elements (202, 203, and 204) in sensing bridge 302. Similarly, the distance between MR element 403 and MR element 203 may be shorter than the distance between MR element 403 and the other MR elements (201, 202, and 204) in sensing bridge 302. In some cases, MR elements 401 and 201 may be of the same type; for instance, if MR element 201 is a TMR element, then MR element 401 may also be a TMR element. Likewise, MR elements 403 and 203 may be of the same type also.

In one example, each of MR elements 401 and 403 can have a configurable baseline resistance. The term “baseline resistance” refers to the minimum or maximum resistance assumed by an MR element when an incident magnetic field is entirely aligned with or completely opposite to the pinning direction of the MR element. The baseline resistance of MR elements 401 and 403 may be adjusted via a control signal provided by controller 304. Each of MR elements 401 and 403 may be implemented as a network of MR pillars extending between two end nodes. Some of these MR pillars may be provided switches that deactivate the MR pillars from the network. The state of these switches is determined by the control signal, which defines the baseline resistance of the MR elements. Throughout the disclosure, the phrase “deactivating an MR element from a network of MR elements” refers to any action that eliminates that MR element's contribution to the total resistance between the network's end nodes. MR elements that are not deactivated are considered active.

An example implementation of MR elements 401 and 403 is depicted in FIG. 8. This figure shows an MR element 800, which comprises MR pillars 802 arranged in a series network between end nodes EN1 and EN2. Each MR pillar 802 has a corresponding bypass switch 804, which, when closed, causes the MR element to be bypassed and no longer contribute to the total resistance between end nodes EN1 and EN2. The switches 804 can be opened and closed based on different bits of a control signal that specifies the baseline resistance of MR element 800. FIG. 8 serves as one possible illustration of an MR element with variable baseline resistance. Those skilled in the art will recognize that some MR pillars 802 may be connected in parallel, in which case one or more switches 804 may be configured to disconnect from at least one of end nodes N1 and N2 those MR pillars (rather than bypass). In other words, the phrase “deactivating an MR pillar” may refer to using a switch to either bypass the MR pillar or disconnect it from at least one end node of the network it is part of.

Current DAC 411 is configured to generate the signal IOFF based on changes in the resistance of one of the MR elements, 401 or 403. The resistance of these MR elements varies according to the magnetic field that affects them. Essentially, the resistance of each MR element can be influenced by an incident magnetic field, like a stray and/or a desired external magnetic field. Therefore, the level of the signal IOFF will change in proportion to the magnetic field affecting either MR element 401 or 403. The signal IOFF is output at node N1 of current DAC 411.

Amplifier 410 serves as a buffer between the voltage supply source of circuit 306 and its other components. Specifically, amplifier 410 receives a voltage supply signal that drives MR elements 401 and 403, as well as it provides a reference current to the current DAC 411.

The topology of circuit 306 is now discussed in more detail. Each of MR elements 401 and 403 may be connected between the reference potential 231 and one of the inputs of amplifier 410. The other input of amplifier 410 may receive the voltage supply signal 417. The output from amplifier 410 may be connected to the gate of transistor 412. The source of transistor 412 may be coupled to MR element 401 through one of switches 416. The other one of switches 416 may be coupled between MR element 401 and the amplifier 410, as shown. In addition, the source of transistor 412 may be coupled to MR element 403 through one of switches 418. The other one of switches 418 may be coupled between MR element 403 and the amplifier 410, as shown. The drain of transistor 412 may be coupled to the current DAC 411 via a PMOS diode 442, as shown. The signal output at the drain of transistor 412 is referred to as signal 413, which serves as a reference signal for current DAC 411. In the present example, DAC 411 is implemented by using PMOS current mirrors. In some implementations, diode 442 may be implemented as an NMOs diode and the DAC 411 may include NMOS current mirrors instead of PMOS current mirrors. Stated succinctly, the present disclosure is not limited to any specific implementation of diode 442 and DAC 411.

The current DAC 411 is now described in further detail. In one example, the current DAC 411 may function as a deck of current mirror sources that can be switched in and out of the output based on a control signal from controller 304. Each current mirror uses signal 413 as a reference. The current DAC 411 is equipped with several switches that manage the individual outputs from the current mirror sources into the final output of the current DAC 411, with the final output being the signal that is produced on node N1. The state of each switch is controlled by a different bit of the control signal provided by controller 304. For example, if the bit is ‘0’, the switch remains open, and if the bit is ‘1’, the switch closes. In the example shown in FIG. 4, current DAC 411 comprises current mirrors 402 and 404. Current mirror 402 connects to node N1 through switch 406, while current mirror 404 connects to node N1 through switch 408. The state of switch 406 is determined by a signal S3-when S3 is ‘0’, switch 406 remains open, and when S3 is ‘1’, switch 406 closes. Switch 408 operates similarly with signal S4; when S4 is ‘0’, switch 408 is open, and when S4 is ‘1’, switch 408 is closed. Both signals, S3 and S4, are generated by controller 304 and are different bits of the control signal provided by the controller. This control signal sets the baseline output level of current DAC 411 and can be used to scale up or down the level of signal IOFF. As noted above, the actual value of signal IOFF would deviate from the baseline output level based on the value of the signal 413. The value of signal 413 may vary based on the value of a stray magnetic field (and/or other magnetic fields) that are incident on MR elements 401 and 403.

The operation of switches 416 and 418 is now discussed in further detail. In the setup shown in FIG. 4, these switches are used to activate or deactivate MR elements 401 and 403. When switches 416 are open, MR element 401 is deactivated, meaning there is no electrical path in circuit 306 from MR element 401 to the source of transistor 412 that does not first pass through the gate of transistor 412. When switches 416 are closed, MR element 401 is activated, creating an electrical path from MR element 401 to the source of transistor 412. Similarly, when switches 418 are open, MR element 403 is deactivated, blocking the electrical path from MR element 403 to the source of transistor 412 without going through the gate of transistor 412 first. When switches 418 are closed, MR element 403 becomes activated, allowing for an electrical path. The state of switches 416 can be controlled by signal S1: when signal S1 is set to ‘0’, switches 416 are open, and when signal S1 is set to ‘1’, switches 416 are closed. Similarly, the state of switches 418 are controlled by signal S2: when signal S2 is set to ‘0’, switches 418 are open, and when signal S2 is set to ‘1’, switches 418 are closed. Signals S1 and S2 may represent different bits of a control signal generated by controller 304. In general when switches 416 are closed and switches 418 are open, such that the current IOFF is generated with MR element 401, the current IOFF may be injected in MR element 201. On the other hand, when switches 416 are open and switches 418 are closed, such that the current IOFF is generated with MR element 403, the current IOFF may be injected in sensing element 203. In some respects, switches 416 and 418 may be configured in such a way, that at any given time, when switches 416 are open, switches 418 are closed, or vice versa. Under this arrangement, switches 416 cannot be open at the same time with switches 418, and MR elements 401 and 403 cannot conduct current simultaneously. In some implementations, sensing elements 201 and 401 may be subjected to a first magnetic field, and sensing elements 203 and 403 may also be subjected to a second magnetic field. The first and second magnetic fields may be different from each other (if sensing bridge 302 is a gradiometer then sensing elements 203 and 201 may be subjected to magnetic fields +B and −B—, assuming no stray field—for example.

The purpose of having two different magnetoresistive (MR) elements in circuit 306 is explained in detail. Generally, the selection of whether signal IOFF is injected into MR element 201 or MR element 203 depends on the polarity (or sign) of the offset of sensing bridge 203. For example, if the offset of sensing bridge 302 has a first polarity (or sign), controller 304 may determine that the injection needs to be done in MR element 201. Accordingly, controller 304 may close switches 416, open switches 418, and apply signal IOFF in MR element 201. In this example, signal IOFF may not be applied in MR element 203. For example, to prevent signal IOFF from being applied in MR element 203, all switches 107 in MR element 203 may be opened, etc. As another example, if the offset of sensing bridge 302 has a second polarity (or sign) that is opposite to the first polarity, controller 304 may determine that the injection needs to be done in MR element 203. Accordingly, controller 304 may close switches 418, open switches 416, and apply signal IOFF in MR element 203. In this example, signal IOFF may not be applied in MR element 201. For example, to prevent signal IOFF from being applied in MR element 201, all switches 107 in MR element 201 may be opened, etc.

Injecting the signal IOFF on this side may increase the output of sensing bridge 302, while also canceling any offset. To ensure high accuracy in offset compensation, it is important for the MR element where the signal IOFF is injected (e.g., one of the MR elements 201 and 203) to be collocated with the MR element that generates the signal IOFF (e.g., one of the MR elements 401 and 403). Thus, the purpose of having two different MR elements is to allow the MR element in sensing bridge 302, where the signal IOFF is injected, to be collocated with the MR element in circuit 306 which generates the signal IOFF.

An example is now provided of a process executed by controller 304 when operating circuit 306. The process involves the following steps:
STEP 1: Controller 304 selects a side of sensing bridge 302 where the signal IOFF will be injected. More specifically, controller 304 selects one of MR elements 201 and 203 as the target location where the signal IOFF is going to be injected. As noted above, the selection may be made based on the polarity of the offset of sensing bridge 302. The polarity of the offset may be determined by observing if the response of sensing bridge 302 is different from zero while no magnetic field is being applied to sensing bridge 302 (i.e., by observing if the zero-field response is zero). If the zero-field response of sensing bridge 302 is less than zero, the polarity of the offset is said to be negative; if the zero-field response is greater than zero, the polarity is said to be positive.
STEP 2: Controller 304 selects one of MR elements 401 and 403 based the bridge offset polarity and/or the MR element that is selected as the target for the injection of signal IOFF. For example, if MR element 201 is selected as the target, controller 304 may select MR element 401 (which may be co-located with MR element 201). As another example, if MR element 203 is selected as the target, controller 304 may select MR element 403 (which may be co-located with MR element 203).
STEP 3: Controller 304 activates the selected one of MR elements 401 and 403 and deactivates the other one. This is done by setting signals S1 and S2 to appropriate values. 5. For example, if MR element 401 is selected at step 2, controller 304 may activate MR element 401 (if it is not already activated) by closing switches 416 and deactivating MR element 403 (if it is not already deactivated) by opening switches 418. As another example, if MR element 403 is selected at step 2, controller 304 may activate MR element 403 (if it is not already activated) by closing switches 416 and deactivating MR element 401 (if it is not already deactivated) by opening switches 418.
STEP 4: Controller 304 injects the signal IOFF by setting the selection signal of the chosen MR element (either 201 or 203) to a value that causes the switching circuit 105 of that MR element to route the signal IOFF to one of the tapping points 103 in that MR element.
STEP 5: Controller 304 disconnects the other MR element (the one not chosen) from circuit 306 by adjusting the selection signal of that MR element to a value that instructs the switching circuit 105 to disconnect it from circuit 306.

Steps 1-7 are provided as an example only. At least some of steps 1-7 may be performed in parallel, performed in a different order, or altogether omitted. In one respect, steps 1-7 are provided to illustrate that controller 304

One advantage of circuit 306 is that it provides controller 304 with fine control over the amount of offset correction applied by the signal IOFF to the final output of sensing bridge 302. To exercise this fine control, controller 304 may select a tapping point within the MR element chosen in step 5 (i.e., one of MR elements 201 and 203) and set the selection signal of that MR element to allow the signal IOFF to be injected at that tapping point. Additionally, controller 304 may adjust the baseline current of DAC 411 to a specific value by appropriately setting signals S3 and S4. Furthermore, controller 304 may modify the baseline resistance of the selected MR element from circuit 306 (i.e., one of MR elements 401 and 403) by activating or deactivating one or more MR pillars that are part of that MR element. Lastly, controller 304 may also modify the level of the voltage supply signal 417 using a variable resistor or a similar device. The selection of any of these operational parameters may be made in accordance with a mathematical model that describes the operation of sensor 300, which is discussed further below. To apply the model, controller 304 may estimate the amount of offset that is present in the output of sensing bridge 302 and then select one or more of the above-described parameters in order to cause the signal IOFF to cancel the offset when it is injected into sensing bridge 302.

In summary, circuit 306 is included in sensor 300 to provide offset cancellation for the output voltage (Vout) of the sensing bridge 302. An offset may appear in the output when sensing bridge is subjected to an electrical imbalance.

Current DAC 411 is provided as one example of a current source that can be used to generate the signal IOFF. However, it would be understood that any suitable type of current source can be used to generate the signal IOFF for as long as the output of the current source is proportional (or otherwise based on) the value of the reference signal 413. Although in the example of FIG. 4, circuit 306 includes two MR elements (i.e., MR elements 401 and 403), in some implementations one of these MR elements may be omitted as well as switches 416 and 418 which couple the MR elements to the source of transistor 412. In some implementations, the remaining one (or either one) of MR elements 401 and 403 may not be collocated with MR elements 201 and 203. Stated succinctly, the present disclosure is not limited to any specific positioning of MR elements 401 and 403.

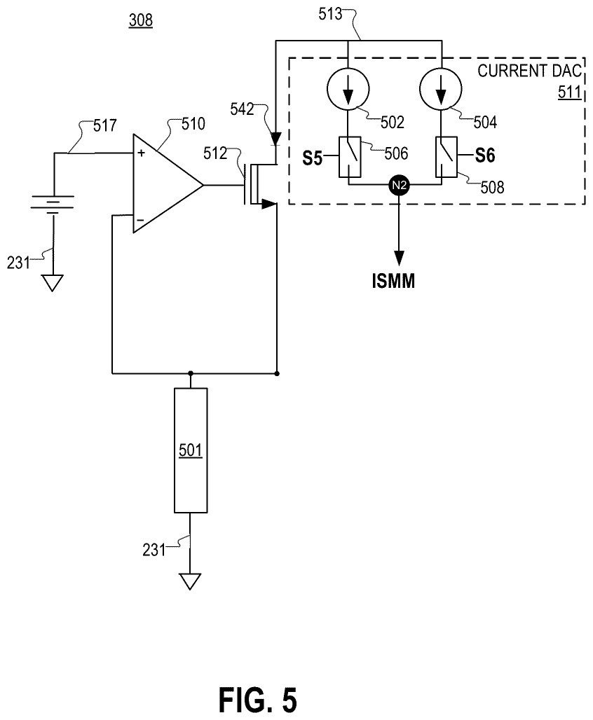

FIG. 5 is a diagram of an example of a sensitivity mismatch trimming circuit 308, according to aspects of the disclosure. As illustrated, circuit 308 may include an amplifier 510, a transistor 512, a non-magnetic resistor 501, and a current DAC 511.

Transistor 512, according to the present example, is a Metal Oxide Field Effect transistor (MOSFET). However, the present disclosure is not limited to using any specific type of transistor; for example, transistor 512 may be a bipolar junction transistor (BJT), and/or any other suitable type of transistor.

Resistor 501 is configured to be a non-magnetic resistor, which means that its resistance remains unchanged when exposed to external magnetic fields. In one example, resistor 501 can be a variable resistor with its resistance value adjusted by controller 304. Alternatively, resistor 501 may have constant resistance.

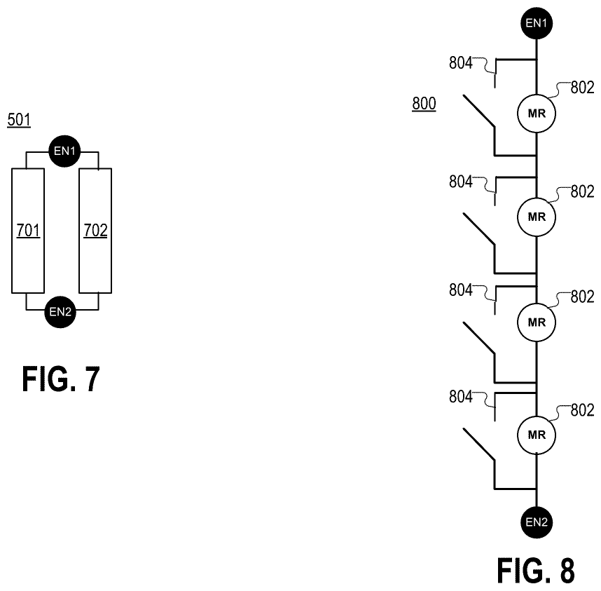

Another possible implementation of resistor 501 is illustrated in FIG. 7. In the example of FIG. 7, resistor 501 includes a first MR element 701 with one pinning direction and a second MR element 702 with an opposite pinning direction. The MR elements 701 and 702 are connected in parallel between two endpoints, EN1 and EN2. Because these MR elements have opposite pinning directions, their respective resistances will drift in opposite directions when exposed to an external magnetic field, such that the equivalent resistance between EN1 and EN2 remains unaffected by fluctuations in the surrounding magnetic field. More precisely, a parallel connection like the one shown in FIG. 7 may keep the conductance of resistor 501 invariant to the magnetic field rather than the resistance. A magnetic invariant resistance could be achieved by connecting MR elements 701 and 702 in series.

In one example, each of MR elements 701 and 702 may be constructed from a different respective network of MR pillars, such as the one discussed earlier in reference to FIG. 8. In this example, resistor 501 can include multiple pairs of MR pillars, where each pair includes (and/or consists of) one MR pillar from MR element 701 and one from MR element 702. Each pair features a unique first and second MR pillar. The resistance of resistor 501 can be adjusted by controller 304 through the activation or deactivation of specific MR pillar pairs. According to this document, an MR pillar pair is considered deactivated when both of its constituent MR pillars are inactive, and it becomes activated when both pillars are active. Additionally, in certain implementations, the MR pillars within resistor 501 may be of the same type, or even identical, to those found in MR elements 201-204 of sensing bridge 302. This similarity is beneficial because it helps ensure that the resistance of resistor 501 will change in tandem with the resistance of MR elements 201-204 when subjected to variations in temperature or other environmental factors, such as humidity or mechanical stress.

The current DAC 511 may be identical to the current DAC 411. Current DAC 511 can receive a reference signal 513 and generate the signal ISMM based on this reference signal. The ISMM signal is output on node N2 of the current DAC 511. In one example, the current DAC 511 may function as a deck of current mirror sources that can be switched in and out of the output based on a control signal from controller 304. Each current mirror uses signal 513 as a reference. As illustrated in FIG. 5, the current DAC 511 may include current mirrors 502 and 504. Current mirror 502 may be coupled to node N2 via a switch 506, while current mirror 504 may be coupled to node N2 via a switch 508. The state of switch 506 is controlled by signal S5: when S5 is set to ‘0’, switch 506 is open; when S5 is set to ‘1’, switch 506 is closed. Similarly, the state of switch 508 is controlled by signal S6: when S6 is ‘0’, switch 508 is open; when S6 is ‘1’, switch 508 is closed. Signals S5 and S6 are generated by controller 304 and are different bits of a control signal provided by the controller. This control signal sets the baseline output level of current DAC 511 and can be used to scale up or down the level of signal ISMM. As noted above, the actual value of signal ISMM would deviate from the baseline output level based on the resistance of resistor 501.

Amplifier 510 is configured to provide a buffer between the voltage supply source of circuit 308 and the other components of the circuit. In this example, amplifier 510 receives a voltage supply signal 517 used to drive resistor 501 and to provide a reference current to the current DAC 511.

The topology of circuit 308 is now described in further detail. Resistor 501 is coupled between the reference potential 231 and one of the inputs of amplifier 510. The other input of amplifier 510 may receive the voltage supply signal 517. The output of amplifier 510 is connected to the gate of transistor 512. The source of transistor 512 is coupled to resistor 501, while the drain of transistor 512 is coupled to the current DAC 511 via a PMOS diode 542. The signal output on the drain of transistor 512 is referred to as signal 513, which serves as a reference signal for current DAC 511. In the present example, DAC 511 is implemented by using PMOS current mirrors. In some implementations, diode 542 may be implemented as an NMOs diode and the DAC 511 may include NMOS current mirrors instead of PMOS current mirrors. Stated succinctly, the present disclosure is not limited to any specific implementation of diode 542 and DAC 511.

An example is now provided of a process executed by controller 304 when operating circuit 308. The process involves the following steps:
STEP A: Controller 304 detects a sensitivity mismatch between leg 211 of sensing bridge 302 and leg 214 (both shown in FIG. 2). In some implementations, the sensitivity mismatch may be sensed by placing next to sensing bridge 302 a calibration coil. In some implementations, the calibration coil may be implemented as a common mode coil 606 (shown in FIG. 6) and/or the feedback coil 606 (shown in FIG. 6). The calibration coil may generate a common mode calibration magnetic field. Controller 304 may measure the calibration magnetic field with sensing bridge 302 and determine if there is a sensitivity mismatch based on whether the measured calibration field matches expected calibration field. Controller 304 may control the calibration coil (e.g., via a corresponding coil driver), and it may know the value of the expected calibration field. The calibration field may be an out of band field (i.e., it may have a different frequency than the magnetic field which sensor 300 is desired to measure) and as such it may not interfere with the measurements taken by sensor 300. The difference between the measured value of the calibration field and the expected value of the calibration field may be referred to as the “error signal of the locally generated calibration field”.
STEP B: Controller 304 selects a side of sensing bridge 302 where the signal ISMM is to be injected, specifically choosing one of the MR elements 202 or 204 as the target for the ISMM signal. For example, if the error signal of the locally generated calibration field has a first polarity (or sign), controller 304 may select MR element 202 as the target for injecting the ISMM signal. If the error signal of the locally generated signal has a second polarity (or sign) that is opposite to the first polarity, controller 304 may select MR element 204 as the target for injecting the ISMM signal.
STEP C: The signal ISMM is injected into the MR element selected at step B by setting the selection signal of the chosen MR element to a value that causes the switching circuit 105 of that MR element to route the signal ISMM to one of the tap points 103 in the MR element.
STEP D: Controller 304 disconnects the other MR element from circuit 308 by setting its selection signal to a value that causes its switching circuit 105 to disconnect it from the circuit 308. For example, if MR element 202 is selected at step B, controller 304 may disconnect MR element 204 from circuit 308. As another example, if MR element 204 is selected at step B, controller 304 may disconnect MR element 202 from circuit 308. Steps A-D are just examples; some of these steps can be performed in a different order, in parallel, or altogether omitted.

Steps A-D are provided as an example only. At least some of steps A-D may be performed in parallel, performed in a different order, or altogether omitted. In one respect, steps A-D are provided to illustrate that controller 304 may monitor the sensitivity of legs 212 and 214, and when a sensitivity mismatch is detected, inject the signal ISMM into one of the MR elements 202 and 204 in order to correct for the mismatch.

One advantage of circuit 308 is that it allows controller 304 to have fine control over the sensitivity mismatch correction imparted by the ISMM signal on the final output of sensing bridge 302. To achieve this fine control, controller 304 can select a tapping point in the chosen MR element (as mentioned in step B) and set the selection signal to inject the ISMM signal at that tapping point. Additionally, controller 304 can set the baseline current of current DAC 511 by adjusting signals S5 and S6 accordingly. Moreover, controller 304 may adjust the resistance of resistor 501 by activating or deactivating one or more MR pillar pairs in resistor 501 or through any other suitable method. Furthermore, controller 304 can adjust the level of the voltage supply signal 517 by using a variable resistor or a similar device. In some implementations, at least one (or all of these operational parameters) may be fixed and not subject to regulation by controller 304.

In summary, circuit 308 is included in sensor 300 to correct for any sensitivity mismatch that there might be between the legs 212 and 214 of sensing bridge 302 or individual MR elements in the sensing bridge 302. Aging, manufacturing variations, and environmental influences, such as changes in temperature, humidity or stress may cause the sensitivity mismatch. The sensitivity mismatch may present itself as a non-zero output signal Vout of the sensing bridge 302 under the present of external stray magnetic fields. If the sensitivity mismatch is zero, the presence of a stray field would not manifest itself as a differential signal on the output of sensing bridge 302 since the bridge would be balanced. By injecting the signal ISMM into the sensing bridge 302, this unwanted term can be diminished or ideally canceled out from the gain of the output Vout of sensing bridge 302, thereby reducing or eliminating the impact of the sensitivity mismatch on the accuracy of sensor 300.

Current DAC 511 is provided as one example of a current source that can be used to generate the signal ISMM. However, it would be understood that in some implementations, any suitable type of current source can be used to generate the signal ISMM. Additionally or alternatively, it would be understood that in some implementations, any suitable type of current source can be used to generate the signal ISMM for as long the resistor 514 is not responsive to magnetic field.

In summary, circuit 308 is included in sensor 300 to provide a correction for any sensitivity mismatch that there might be between the sensing elements of sensing bridge 302. An offset may appear in the output when sensor 300 is exposed to a stray magnetic field, which acts as a form of noise. This stray magnetic field is different from the magnetic field that sensor 300 is intended to measure. For instance, if sensor 300 is a current sensor, the magnetic field of interest is generated by the electrical current flowing through a target. Similarly, if sensor 300 is a position sensor, the relevant magnetic field may be produced by a gear or another magnetic object. The presence of the stray magnetic field can alter the true value of the sensor's output, either by adding or subtracting from it. By injecting the signal ISMM into the sensing bridge 302, this unwanted term can be diminished or ideally canceled out, thereby reducing or eliminating the impact of the stray magnetic field on the accuracy of sensor 300.

A mathematical model is now provided of the operation of sensing bridge 302. The mathematical model assumes that no magnetic fields are incident on sensing bridge 302. The mathematical model is provided to illustrate how the values of different operational parameters of circuits 306 and 308 affect the output of sensing bridge 302.

When signals IOFF and ISMM are both injected into the sensing bridge 302, the output Vout of sensing bridge 302 may be described by equation 1 below. Equation 1 assumes that no magnetic field is being applied to sensing bridge 302.

Vout=Voff±IOFF*(K2)/2*R_{dot}±ISMM*(K′2)/2*R_{dot} (1)

where Vout is the output of sensing bridge 302, Voff is the offset that is present in the output of sensing bridge 302 without any correction applied, IOFF is the value of signal IOFF which is generated by the offset trimming circuit 306, and ISMM is the value of signal ISMM which is generated by the sensitivity mismatch trimming circuit 308. K2 is the number of MR pillars between a tap point that is selected by controller 304 in the one of MR elements 201 and 203 which is selected at step 5 and the nearest one of nodes V1 and V2 of sensing bridge 302. K2′ is the number of MR pillars between a tap point that is selected by controller 304 in one of the one MR elements 202 and 204 (selected at step B) and a corresponding one of nodes V1 and V2 of sensing bridge 302. R_{dot} is the individual resistance of each of the MR pillars that make up MR elements 201-204, 401, and 403.

When only signal IOFF is injected into the sensing bridge 302, the output Vout of sensing bridge 302 may be described by equation 2 below:

Vout=Voff±IOFF*(K2)/2*R_{dot} (2)

The value of the voltage supply signal 417 may be described by equation 3 below:

S₄₁₇=K₁*Vcc (3)

where S₄₁₇ is the value of the voltage supply signal 417, K₁ is a scaling coefficient, and Vcc is the supply voltage of sensing bridge 302. In some implementations, the value of K₁ may be set by using a variable resistor, or another similar device, whose resistance is set by controller 304.

The output of the circuit 306 is defined by equation 3 below:

$$IOFF = \pm {K}_{DAC 1} * \frac{{S}_{417}}{{K}_{0} * {R}_{dot}} \qquad ( 4 )$$

where K₀ is the number of active MR pillars in the one of MR elements 401 and 403 which is selected at step 3 (and used to generate reference signal 413), R_{dot} is the individual resistance of each of the active MR pillars, and K_{DAC1} is the level of the baseline current of current DAC 411 that is specified via signals S3 and S4.

Combining equations 2 and 4, yields equation 5 below:

$$Vout = Voff \pm {K}_{DAC 1} * \frac{{S}_{417}}{{K}_{0}} * ( K 2 ) / 2 \qquad ( 5 )$$

The value of signal 517 may be described by equation 6 below:

S₅₁₇=K₄*Vcc (6)

where S₅₁₇ is the value of the voltage supply signal 517, K₄ is a scaling coefficient, and Vcc is the supply voltage of sensing bridge 302. In some implementations, the value of K₄ may be set by using a variable resistor, or another similar device, whose resistance is set by controller 304.

The output of the trimming circuit 308 is defined by equation 7 below:

$$ISMM = \pm {K}_{DAC 2} * \frac{{S}_{517}}{{K}_{5} * {R}_{dot \_ fixed}} \qquad ( 7 )$$

where K_{DAC2} is the level of the baseline current of current DAC 511 that is specified by signals S5 and S6, S₅₁₇ is the value of the voltage supply signal 517, K₅ is the number active MR pillars in resistor 501, and Rdot_fixed is the sum of the individual resistance of both MR pillars that make up any of the MR pillar pairs.

Combining equations 4, 5, and 7, yields equation 8 below which also described the output of sensing bridge 302 when both of offset trimming and sensitivity trimming are performed on sensing bridge 302:

$$Vout = Voff \pm {K}_{DAC 1} * \frac{{S}_{417}}{{K}_{0}} * ( K 2 ) / 2 \pm {K}_{DAC 2} * \frac{{S}_{417} * {R}_{dot} ( B )}{{K}_{5} * {{R}_{dot}}_{fixed}} * ( {K}^{′} 2 ) / 2 \qquad ( 8 )$$

FIG. 6 is a diagram of a magnetic field sensor 600, according to aspects of the disclosure. The magnetic field sensor 600 includes magnetoresistance circuitry 16′, analog circuitry 22′, digital circuitry 26′, feedback circuitry 32′, feedback coil circuitry 36′, and common mode coil circuitry 636′.

In one example, the magnetoresistance circuitry 16′ includes a sensing bridge 132 and a driver 134 that drives the sensing bridge 132. The sensing bridge 132 may receive a magnetic-field error signal 186, which is converted into a differential output voltage signal called herein an error signal Vᵢ. Under the nomenclature of the present disclosure, the signal Vi is called an error signal because it carries an error, but it can also be thought of as the raw output of sensing bridge 132. The sensing bridge 132 may be a half-bridge or a full bridge (e.g., a Wheatstone bridge circuit). According to the present example, the sensing bridge 132 includes a plurality of tunneling magnetoresistance elements (TMRs). However, the present disclosure is not limited to any specific type of sensing element being included in the sensing bridge 132. For example, in some implementations, the sensing bridge 132 may include giant magnetoresistance elements (GMRs), Hall elements, and/or any other suitable type of magnetic field sensing element, for as long as the magnetic field sensing element is formed of sub-units (such as pillars), which could be selectively turned on and off to adjust the resistance of the sensing element. Although, in the present example, circuit 132 is a bridge circuit, alternative implementations are possible in which circuit 132 is a serial circuit and/or any other suitable type of circuit. Stated succinctly, the present disclosure is not limited to any specific topology for connecting the magnetic field sensing elements that are part of sensor 600.

In one example, the analog circuitry 22′ may include a modulator 136, an amplifier 140, a demodulator 170, and an analog-to-digital converter (ADC) 142.

The modulator 136 receives the error signal Vᵢ from the magnetoresistance circuitry 16′ and modulates the error signal Vᵢ at a frequence F1 to form a baseband signal. The baseband signal is amplified by the amplifier 140 by a gain A. The amplified signal is demodulated at the frequency F1 by demodulator 170. The amplified baseband signal is converted from an analog signal to a digital signal by the ADC 142. In one example, the ADC 142 may be a sigma-delta ADC.

The digital circuitry 26′ is an example of the digital circuitry 26. In one example, the digital circuitry 26′ may include a cascaded integrator-comb (CIC) filter 144, a filter 146, a temperature correction circuit 148, a temperature sensor 150, a bandwidth (BW) selection circuit 152, and a programming and memory circuit 158.

The CIC filter 144 receives the digital baseband signal from the ADC 142. The filter 146 may be a low pass filter configured to filter noise and other artifacts from output of the CIC filter 144 to produce an output voltage signal Vₒ. The temperature correction circuit 148 may scale the output voltage signal Vₒ according to temperature (e.g., a temperature measured by the temperature sensor 150). The BW selection circuit 152 provides a further low-pass filtering with a selectable cut-off frequency to generate the output signal 50.

In one example, the feedback circuitry 32′ includes a filter 162, and a digital-to analog converter (DAC) 166. The filter 162 may be a low pass filter configured to filter noise and other artifacts from output of the CIC filter 144. The DAC 166 receives the filtered digital output signal from the filter 162 and converts the filtered digital output signal to an analog signal and converts the filtered digital output signal from a digital voltage signal to an analog current signal. The analog current signal from the DAC 166 is provided to a feedback coil driver 112. feedback coil 106

In one example, the feedback coil circuitry 36′ includes a feedback coil 106 and the feedback coil driver circuit 112. The AC current signal I_{SC} enables the feedback coil driver circuit 112 to power the feedback coil 106 to produce the feedback magnetic field signal 180. In one example, the feedback coil 106 has a coupling factor Ksc of 800 Gauss per amp. Furthermore, in one example, the common mode coil circuitry 36′ may include a coil driver 612 and common mode coil 606. The coil driver 612 may be controlled by controller 304 (shown in FIG. 3). In one example, feedback coil 106 may include two or more segments that are coupled in series and formed in different physical locations (e.g., adjacent to different elements of sensing bridge 132). In one example, common mode coil 606 may include two or more segments that are coupled in series and formed in different physical locations (e.g., adjacent to different elements of sensing bridge 132). Common mode coil 606 may be configured to generate a common mode magnetic field 680, whereas feedback coil 106 may be configured to generate a feedback magnetic field. The common mode magnetic field 680 may be a magnetic field that is rejected by sensing bridge 132, when sensing bridge 132 is balanced. In other words, when sensing bridge 132, when sensing bridge 132 is balanced, sensing bridge 132 would exhibit no response to the common mode magnetic field. By contrast, the feedback magnetic field 180 may be a magnetic field that is sensed (i.e., not rejected) by sensing bridge 132.

The magnetic field sensor 600 may be analyzed in terms of the error signal Vᵢ, the output Vₒ and the reflected signal 124 as defined as:

$${V}_{i} = ( {B}_{ms} + {B}_{cm} \cdot \frac{Δ S}{{S}_{TMR}} ) \cdot {S}_{TMR} - {V}_{o} \cdot d \cdot {K}_{SC} \cdot {S}_{TMR} + Voff ,$$

where Bₘₛ is the magnetic field directly coupled from the magnetic field source 120, is the field directly coupled from the

$${V}_{0} = {V}_{i} \cdot A = ( ( {B}_{ms} + {B}_{cm} \cdot \frac{Δ S}{{S}_{TMR}} ) \cdot {S}_{TMR} - {V}_{o} \cdot d \cdot {K}_{SC} \cdot {S}_{TMR} + Voff ) \cdot A ,$$

$${I}_{SC} = {V}_{o} \cdot d ,$$

where: S_{TMR} is TMR sensitivity, AS is the bridge sensitivity mismatch, d is voltage-to-current feedback gain, A·S_{TMR} is loop gain, Bₘₛ is magnetic field directly coupled from the magnetic source, Voff is the bridge offset

The output signal Vₒ may be defined as follows:

$${V}_{o} = \frac{( ( {B}_{ms} ( x ) + {B}_{cm} \cdot \frac{Δ S}{{S}_{TMR}} ) \cdot {S}_{TMR} + Voff ) \cdot A}{1 + d \cdot {K}_{SC} \cdot {S}_{TMR} \cdot A}$$

and the system gain (for B_{cm}=Voff=0) of the magnetic field sensor 600 may be expressed as:

$$\frac{{V}_{o}}{{B}_{ms}} = \frac{{S}_{TMR} \cdot A}{1 + d \cdot {K}_{SC} \cdot {S}_{TMR} \cdot A} .$$

For S_{TMR}·A>>1, then the system gain of the magnetic field sensor 600 becomes

$$\frac{1}{d \cdot {K}_{SC}} .$$

For a high enough loop gain, the system gain is independent of STMR

Thus, the proportionality factor depends on the inverse of the voltage-to-current feedback gain d and the secondary coil coupling factor Ksc.

As described herein, the non-linear behavior of the TMRs in sensing bridge 132 is masked by the magnetic-field closed-loop approach and the overall system gain does not depend on the sensitivity of any of the TMRs in sensing bridge 132. In some implementations, magnetic field source 120 may be a rotating target, in which case the signal output from sensing bridge 132 may be an alternating current (AC) signal.

Magnetic field sensor 600 may be provided with an autozero circuit 135. The autozero circuit 135 may be used to correct any resistive imbalance that might exist between the TMRs in sensing bridge 132. As used herein, the phrase “correct resistive imbalance” refers to making the respective resistances of all (or at least two) of the TMRs equal (or close to being equal—i.e., within a predetermined distance from each other). The autozero circuit 135 may be configured to generate a signal COUNT and provide it to sensing bridge 132, after which the value of the signal COUNT may be used by control circuitry in sensing bridge 132 to select the appropriate resistance for at least one of the TMRs in the sensing bridge 132. In some implementations, the selection of appropriate resistance can be performed in the manner discussed in U.S. patent application Ser. No. 18/527,675 entitled “LOW RESIDUAL OFFSET SENSOR” (hereinafter “the related application”) which is hereby incorporated by reference herein in its entirety.

In one example, the term “sensing signal that is at least in part generated by one or more sensing elements” may refer to any of: (i) the raw output (Vi) of sensing bridge 132, the output of modulator 136, the output of ADC 142, the output of CIC 144, the output of filter 146, or the output of TC 148. The sensing signal, in addition to indicating a useful quantity that is desired to be measured, may also carry noise, offset, and/or other sources of error. Stated succinctly, the phrase “sensing signal that is at least in part generated by one or more sensing elements” may refer to the raw output of the one or more sensing elements or any other signal that is generated by processing the raw output.

Magnetoresistance circuitry 16′ may be provided with the controller 304, the offset trimming circuit 306, and the sensitivity mismatch trimming circuit 308. The controller 304 and the circuits 304-308 may be configured in the manner discussed above with respect to FIG. 2. The sensing bridge 132 may include a plurality of magnetic field sensing elements. In some implementations, each of the sensing elements may be configured as discussed in the related application. Namely, each of the sensing elements may include a network of MR pillars and it may be provided with a first switching circuitry that is configured to connect and disconnect some of the pillars from the rest of the sensing bridge. In other words, the appropriate resistance of any of the sensing elements in sensing bridge 132 is selected by connecting or disconnecting the MR pillars that form the sensing element from the rest of the sensing bridge 132.

In addition, each (or at least one) of the sensing elements in the sensing bridge 132 may be provided with a second switching circuitry. The second switching circuitry may be the same or similar to the switching circuit 105, which is discussed above with respect to FIG. 1. The second switching circuitry may be configured to receive a signal and inject the signal at one of a plurality of tap points in the sensing element. The tap point where the signal is generated may be selected by a control signal that is fed into the second switching circuitry by controller 304.

The offset trimming circuit 306 may be configured as discussed above with respect to FIG. 4, and it may be arranged to inject the signal IOFF into at least one of the sensing elements in the sensing bridge 132. The sensitivity trimming circuit may be configured as discussed above with respect to FIG. 5, and it may be arranged to inject the signal ISMM into one or more of the sensing elements in sensing bridge 132.

In some respects, the inclusion of circuits 306 and 308 into any of sensors 300 and 600 is advantageous because it may improve the Common Mode Rejection Ratio (CMRR) of the sensor. The technique presented with respect to circuits 306 and 308 is adaptable for both baseband (DC) and modulated (AC) sensors, and it can be applied to either open-loop or closed-loop magnetic architectures, although it is particularly suited for the latter.

The techniques presented throughout the disclosure are useful for correcting offset and sensitivity mismatch, specifically in sensing bridges with a low dot count (i.e., low MR pillar count) per MR element. Such low dot counts are typical in TMR-based magnetic closed-loop systems, where maximizing the feedback coil coupling factor is crucial. This requirement necessitates a compact layout to concentrate the maximum amount of magnetic flux.

The techniques presented throughout the disclosure introduce a compensation current (e.g., IOFF and/or ISMM) generated from MR pillars (or dots) subjected to the same magnetic field as the ones in the sensing bridge (e.g., sensing bridge 302). This current is injected into the bridge at a specific injection point. Consequently, the total number of dots required to compensate for offset and sensitivity mismatch can be significantly reduced compared to more conventional designs and does not have to be actively part of the bridge.

Reducing the total amount of dots eases the constraints on feedback coil design, as the TMR array (or another MR array)—comprising both the bridge and the compensation dots—can now be smaller, allowing for better optimization of the feedback coil. Closed-loop magnetic systems are highly desirable for high-accuracy applications because they stabilize transducer sensitivity under various environmental conditions. The techniques presented throughout the disclosure are designed to trim offset and correct sensitivity mismatches in a TMR sensing bridge—two critical factors affecting overall accuracy—making it particularly suited for these magnetic closed-loop systems, given the low dot count in the active TMR elements. However, it will be understood that the techniques can also be used in other MR-based systems, such as systems that use a GMR sensing bridge or an AMR sensing bridge.

The term MR pillar may refer to the constituent building block of an MR element. An MR element may, in theory, consist of a single MR pillar. However, in most practical applications MR elements are formed of a network of MR pillars. In some implementations, the term MR pillar may refer to any suitable type of magnetoresistive element. Additionally, or alternatively, the term MR pillar may refer to a structure including a fixed-magnetization layer and a variable-magnetization layer that are spaced apart from each.

As noted above, an MR element may be a network of MR pillars. In this regard, the term “terminal” of an MR element may refer to a node (or point in a sensing bridge) that is either upstream or downstream from all MR pillars that make up the MR element. The terms upstream and downstream refer to the flow of electrical current in the sensing bridge 302 between the voltage source Vcc and the potential reference 132.

In the example of FIG. 2, all MR elements in sensing bridge 302 are identical to MR element 100 (shown in FIG. 1). However, in alternative implementations, only one or fewer than all of the MR elements in sensing bridge 302 may be the same or similar to MR element 100. The rest may include conventional MR elements and/or non-magnetic resistors. In the example of FIG. 2, multiple MR elements are arranged to receive the signals ISMM and IOFF. However, in alternative implementations, only one MR element in sensing bridge 302 may be arranged to receive signal IOFF and/or only one MR element in sensing bridge 302 may be arranged to receive the signal ISMM.

In the example of FIGS. 1-8, each of MR elements 201, 202, 203, 204, 401, 403, 701, and 702 is formed of the same type of and/or otherwise identical MR pillars. However, the present disclosure is not limited thereto. For example, at least two of the MR elements may be formed of different types of MR pillars and/or otherwise different MR pillars. Although, in the example of FIGS. 1-8, MR elements 201, 202, 203, 204, 401, 403, 701, and 702 are formed of MR pillars, in alternative implementations a different type of MR structure may be used to form MR elements 201, 202, 203, 204, 401, 403, 701, and 702, such as a planar MR structure. Although in the example of FIGS. 1-8, each of the MR pillars is a TMR pillar, in alternative implementations, any of the MR pillars may use a different type of MR technology, such as GMR, MTJ, or AMR. Stated succinctly, the present disclosure is not limited to using any specific type of magnetoresistance technology.

FIGS. 1-8 are provided as an example only. Throughout the disclosure, like reference numerals refer to like parts. The examples provided with respect to FIGS. 1-8 are not mutually exclusive and may be combined, modified, or adapted in various ways by those skilled in the art without departing from the scope and spirit of the invention defined by the appended claims. Like numerals refer to like parts.

A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A sensor comprising:
a sensing bridge including a first primary magnetoresistance (MR) element, a second primary MR element, a third primary MR element, and a fourth primary MR element, the first primary MR element being coupled in series with the second primary MR element to form a first leg of the sensing bridge, the third primary MR element being coupled in series with the fourth primary MR element to form a second leg of the sensing bridge, the first leg being coupled in parallel with the second leg, the first primary MR element including a first network of MR structures, the second primary MR element including a second network of MR structures, the third primary MR element including a third network of MR structures, and the fourth primary MR element including a fourth network of MR structures;
an offset trimming circuit that includes one or more secondary MR elements and a first current source, wherein the first current source and the one or more secondary MR elements are configured to generate an offset compensation signal and inject the offset compensation signal in one of the first network or the third network; and
a sensitivity mismatch trimming circuit that includes a non-magnetic resistor and a second current source, wherein the second current source and the non-magnetic resistor are configured to generate a sensitivity compensation signal and inject the sensitivity compensation signal in at least one of the second network and/or the fourth network.

2. The sensor of claim 1, further comprising a controller, wherein:
the offset trimming circuit includes a transistor, the transistor including a first terminal that is coupled to the first current source, a second terminal that is coupled to the one or more secondary MR elements, and a control terminal that is arranged to receive a first supply voltage,
the secondary MR elements include a first secondary MR element and a second secondary MR element;
the offset trimming circuit includes a first switch and a second switch;
the first secondary MR element is collocated with the first primary MR element and the second secondary MR element is collocated with the second primary MR element; and
the controller is configured to select one of the first secondary MR element and the second secondary MR element, and cause the first switch and the second switch to connect the selected one of the first and second secondary MR elements to the second terminal of the transistor and disconnect the other one of the first and second secondary MR elements from the second terminal of the transistor.

3. The sensor of claim 1, wherein the non-magnetic resistor includes a first secondary MR element that has a first pinning direction and a second secondary MR element that has a second pinning direction that is opposite to the first pinning direction.

4. The sensor of claim 1, further comprising a controller that is configured to select a tap point in one of the first network and the second network and inject the offset compensation signal at the selected tap point.

5. A sensor comprising:
a sensing bridge including a plurality of primary MR elements;
an offset trimming circuit that includes one or more secondary MR elements, and a current source,
wherein the current source is configured to generate an offset compensation signal based on a reference signal that is produced at least in part by the one or more secondary MR elements, and inject the offset compensation signal in the sensing bridge.

6. The sensor of claim 5, wherein:
the offset trimming circuit further includes a transistor, the transistor having a control terminal, a first terminal, and a second terminal, the control terminal being arranged to receive a supply voltage, the first terminal being coupled to the current source, and the second terminal being coupled to the one or more secondary MR elements, and
each of the primary and secondary MR elements includes a different respective network of MR structures.

7. The sensor of claim 5, wherein a given one of the primary MR elements includes a network of MR structures, and injecting the offset compensation signal into the sensing bridge includes routing the offset compensation signal to a tapping point that is situated between two of the MR structures that are coupled to each other in series.

8. The sensor of claim 5, wherein a given one of the primary MR elements includes a network of MR structures, and injecting the offset compensation signal into the sensing bridge includes routing the offset compensation signal to a tapping point in the network that is situated upstream from a first subset of the MR structures and downstream from a second subset of the MR structures.

9. The sensor of claim 5, wherein a first one of the primary MR elements includes a network of MR structures, a second one of the primary MR elements includes a second network of MR structures, and injecting the offset compensation signal into the sensing bridge includes routing the offset compensation signal to a tapping point that is situated between the first and second networks.

10. The sensor of claim 5, wherein the current source includes a current mirror that uses the reference signal as a reference.

11. The sensor of claim 5, wherein:
the offset compensation signal is output by the current source on an output node of the current source; and
the current source includes a plurality of current mirrors and a plurality of switches, each of the current mirrors being a coupled to the output node of the current source via a respective one of the plurality of switches.

12. The sensor of claim 11, further comprising a controller that is configured to set a baseline level for the offset compensation signal by selectively opening and closing one or more of the plurality of switches.

13. The sensor of claim 5, further comprising a controller, wherein:
the primary MR elements include a first primary MR element and a second primary MR element;
the secondary MR elements include a first secondary MR element and a second secondary MR element;
the offset trimming circuit includes a first switch and a second switch;
the first secondary MR element is collocated with the first primary MR element and the second secondary MR element is collocated with the second primary MR element; and
the controller is configured to detect a direction of a magnetic field that is incident on the sensing bridge, select one of the first secondary MR element and the second secondary MR element, and cause the first switch and the second switch to connect the selected one of the first and second secondary MR elements to the second terminal and disconnect the other one of the first and second secondary MR elements from the second terminal.

14. The sensor of claim 5, further comprising a controller that is configured to select a tap point in one of the primary MR elements and inject the offset compensation signal at the selected tap point.

15. The sensor of claim 5, further comprising a controller, wherein:
each of the secondary MR elements includes a respective network of MR structures; and
the controller is configured to select a baseline resistance of any of the one or more secondary MR elements by activating and/or deactivating one or more MR structures that are part of the secondary MR element.

16. The sensor of claim 5, wherein the each of the primary MR elements and each of the secondary MR elements includes a tunnelling magnetoresistance (TMR) element.

17. A sensor comprising:
a sensing bridge including a plurality of primary MR elements;
a sensitivity trimming circuit that includes a non-magnetic resistor, and a current source,
wherein the current source is configured to generate a sensitivity compensation signal based on a reference signal that is produced at least in part by the non-magnetic resistor, and inject the sensitivity compensation signal in the sensing bridge.

18. The sensor of claim 17, wherein:
the sensitivity trimming circuit further includes a transistor, the transistor having a control terminal, a first terminal, and a second terminal, the control terminal being arranged to receive a supply voltage, the first terminal being coupled to the current source, and the second terminal being coupled to the non-magnetic resistor;
the non-magnetic resistor includes a first secondary MR element that has a first pinning direction and a second MR element that has a second pinning direction that is opposite to the first pinning direction, and
each of the primary and secondary MR elements includes a different respective network of MR structures, each respective network of MR structures including identical MR structures to those in the rest of the networks of MR structures.

19. The sensor of claim 17, wherein the non-magnetic resistor includes a first secondary MR element that has a first pinning direction and a second MR element that has a second pinning direction that is opposite to the first pinning direction.

20. The sensor of claim 17, wherein a given one of the primary MR elements includes a network of MR structures, and injecting the sensitivity compensation signal into the sensing bridge includes routing the sensitivity compensation signal to a tapping point that is situated between two of the MR structures that are coupled to each other in series.

21. The sensor of claim 17, wherein a given one of the primary MR elements includes a network of MR structures, and injecting the sensitivity compensation signal into the sensing bridge includes routing the sensitivity compensation signal to a tapping point in the network that is situated upstream from a first subset of the MR structures and downstream from a second subset of the MR structures.

22. The sensor of claim 17, wherein a first one of the primary MR elements includes a network of MR structures, a second one of the primary MR elements includes a second network of MR structures, and injecting the offset compensation signal into the sensing bridge includes routing the offset compensation signal to a tapping point that is situated between the first and second networks.

23. The sensor of claim 17, wherein the current source includes a current mirror that uses the reference signal as a reference.

24. The sensor of claim 17, wherein:
the sensitivity compensation signal is output by the current source on an output node of the current source; and
the current source includes a plurality of current mirrors and a plurality of switches, each of the current mirrors being a coupled to the output node of the current source via a respective one of the plurality of switches.

25. The sensor of claim 17, further comprising a controller that is configured to set a baseline level for the sensitivity compensation signal by selectively opening and closing the plurality of switches.

26. The sensor of claim 17, further comprising a controller, wherein the non-magnetic resistor includes a variable resistor, and the controller is configured to select a resistance of the non-magnetic resistor.

27. The sensor of claim 17, further comprising a controller that is configured to select a tap point in one of the primary MR elements and inject the sensitivity compensation signal at the selected tap point.

28. The sensor of claim 17, wherein the each of the first primary MR element, the second primary MR element, and the secondary MR elements includes a tunnelling magentoresistance (TMR) element.
